(19) United States
(12) Patent Application Publication
(10) Pub. No.: US 2025/0220898 A1
(43) Pub. Date: Jul. 3, 2025

(54) FLASH MEMORY AND METHOD FOR FORMING THE SAME

(71) Applicant: Winbond Electronics Corp., Taichung City (TW)

(72) Inventor: Taku KONDO, Taichung City (TW)

(21) Appl. No.: 18/402,040

(22) Filed: Jan. 2, 2024

(51) Int. Cl. H10B 41/35; H01L 21/3115; H01L 21/764; H01L 29/66

(52) U.S. Cl. CPC H10B 41/35; H01L 21/31155; H01L 21/764; H10D 30/0411

(57) ABSTRACT

A method for forming a flash memory includes forming an isolation layer to surround a plurality of active regions, forming a plurality of gate stacks across the active regions and the isolation layer, implanting a dopant into an upper portion of the isolation layer to form a doped isolation layer, partially recessing the doped isolation layer, and forming a dielectric material over the plurality of gate stacks, the plurality of active regions, and the doped isolation layer.

### BACKGROUND

### Field of the Disclosure

The present disclosure relates to flash memory and a method for forming the flash memory, and in particular, it relates to flash memory with an air gap.

### Description of the Related Art

In order to increase the element density in a flash memory device and improve its overall performance, existing technologies for fabricating flash memory devices must focus on continuously scaling down the size of the elements. However, in scaling down the minimum size of the features (e.g., contacts), new challenges arise. Therefore, there is a need in the industry to improve the method of fabricating flash memory devices to overcome problems caused by reducing the size of the elements.

### SUMMARY

In some embodiments of the disclosure, a flash memory is provided. The flash memory includes a plurality of active regions over a substrate, a first isolation layer surrounding lower portions of the active regions, a plurality of gate stacks across the active regions, and a second isolation layer surrounding upper portions of the active regions. An air gap is located in the second isolation layer and includes a first portion between a first gate stack and a second gate stack in the plurality of gate stacks and a second portion between a first active region and a second active region in the plurality of active regions.

In some embodiments of the disclosure, a method for forming a flash memory is provided. The method includes forming an isolation layer to surround a plurality of active regions, forming a plurality of gate stacks across the active regions and the isolation layer, implanting a dopant into an upper portion of the isolation layer to form a doped isolation layer, partially recessing the doped isolation layer, and forming a dielectric material over the gate stacks, the active regions, and the doped isolation layer.

### BRIEF DESCRIPTION OF THE DRAWINGS

In accordance with some embodiments of the present disclosure, it can be further understood by reading the subsequent detailed description and examples with references made to the accompanying drawings, wherein:

FIG. 1 illustrates a plan view (layout) of a flash memory.

FIGS. 2A-1 through to 2G-3 illustrate cross-sectional views of forming a flash memory at various stages, in accordance with some embodiments of the present disclosure.

FIG. 3 is a modification of the flash memory of FIG. 2G-2, in accordance with some embodiments of the present disclosure.

### DETAILED DESCRIPTION

The present disclosure is described in detail with reference to the figures of the embodiments of the present disclosure. It should be appreciated, however, that the present disclosure can be embodied in a wide variety of implements and is not limited to embodiments described in the disclosure. The thickness of the layers and regions in the figures may be enlarged for clarity, and the same or similar reference numbers in the figures are denoted as the same or similar elements.

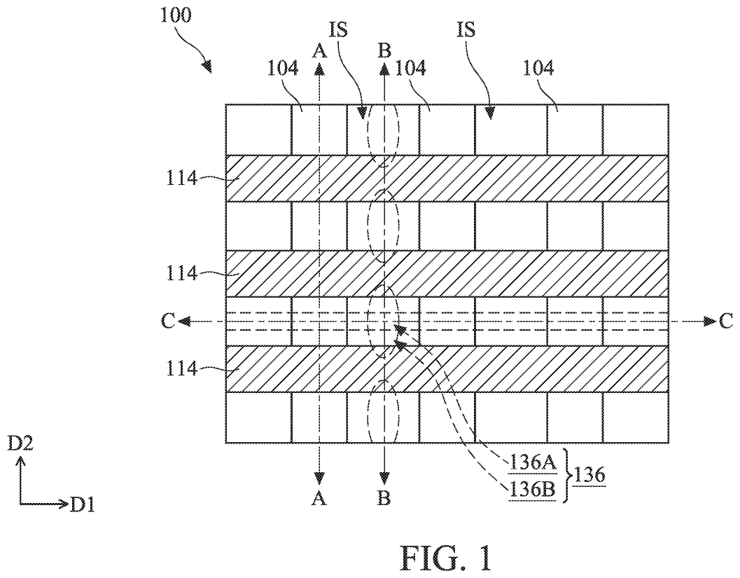

FIG. 1 illustrates a plan view (layout) of a flash memory 100. According to some embodiments of the present disclosure, as shown in FIG. 1, the flash memory 100 includes multiple active regions 104 and an isolation structure IS surrounding the active regions 104. In some embodiments, the active regions 104 are semiconductor strips, and the isolation structure IS may include multiple layers of dielectric material.

The flash memory 100 further includes multiple gate stacks 114 formed across the active regions 104 and the isolation structure IS. In some embodiments, the flash memory 100 may be used to form NAND-type flash memory devices. Each of the gate stacks 114 includes multiple conductive layers which may be configured as the floating gate, the control gate and/or the word line of the flash memory device.

The plan view only shows some components of the flash memory 100 for brevity and clarity. Some other components of the flash memory 100 may be shown in FIGS. 2A-1 through 2G-3. For ease of illustration, FIG. 1 illustrates reference directions, in that directions D1 and D2 are horizontal directions. The first direction D1 is parallel to the longitudinal axes of the gate stacks 114, and the second direction D2 is parallel to the longitudinal axes of the active regions 104. In some embodiments, the first direction D1 is substantially perpendicular to the second direction D2.

In order to improve electrical characteristics of the flash memory devices, e.g., data retention, and/or cross-talk between cells during operations such as program, erase, etc., air gaps 136 may be formed in the isolation structure IS. The air gaps 136 may include first portions 136A which extends in the first direction D1 between neighboring gate stacks 114 and second portions 136B which are formed between neighboring active regions 104 and neighboring gate stacks 114. The air gaps 136 are configured to reduce parasitic capacitance between neighboring gate stacks 114. For illustrative purpose, only a first portion 136A and a row of second portions 136B of the air gaps 136 are shown in FIG. 1. However, the first portions 136A may be formed between any two neighboring gate stacks 114, and the rows of second portions 136B may be formed between any two neighboring active regions 104.

FIG. 1 further illustrates reference cross-sections, in that cross-section A-A is a plane that is parallel to the second direction D2 and passes through an active region 104, cross-section B-B is a plane that is parallel to the second direction D2 and passes through the isolation structure IS, and cross-section C-C is a plane that is parallel to the first direction D1 and passes through between the gate stacks 114.

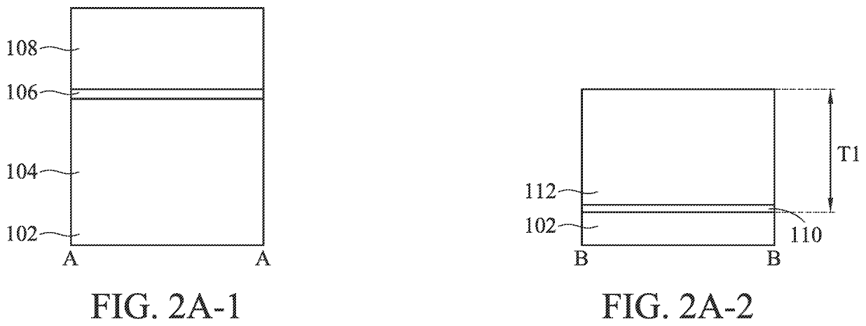

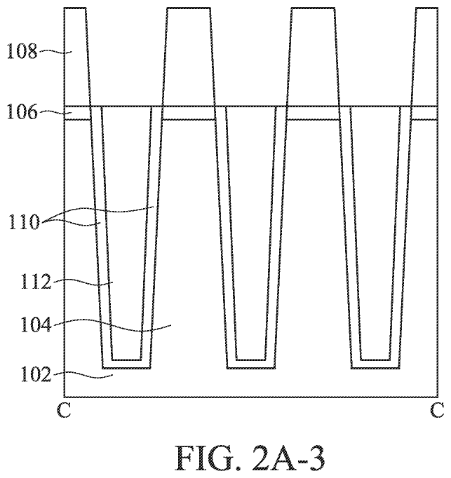

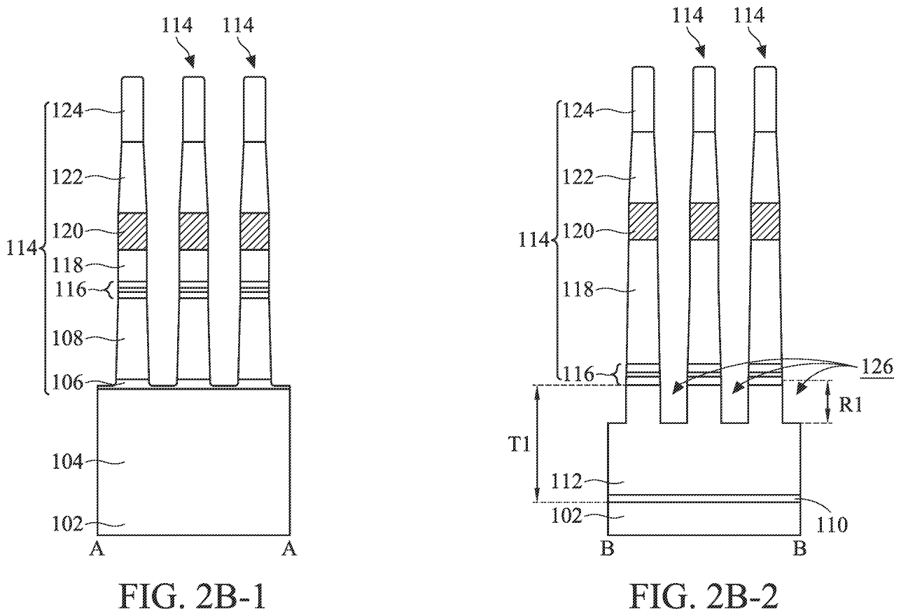

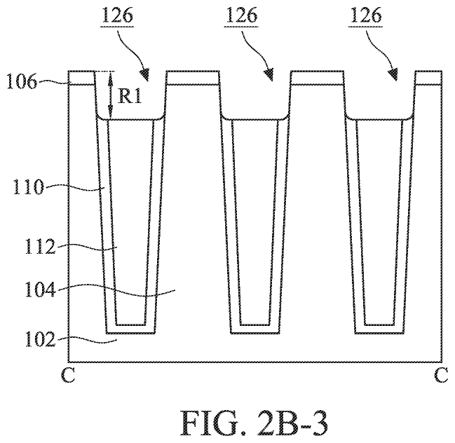

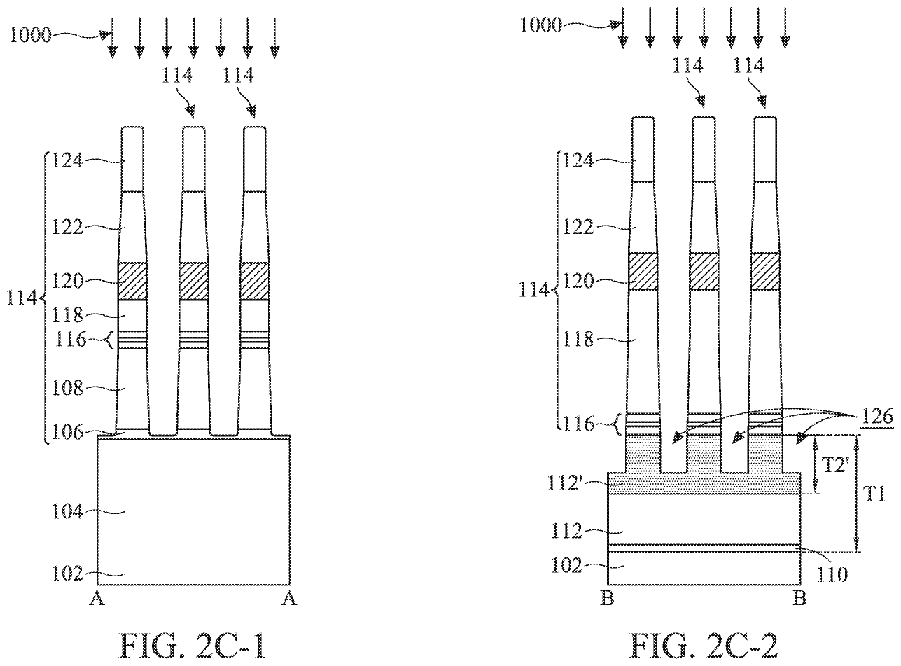

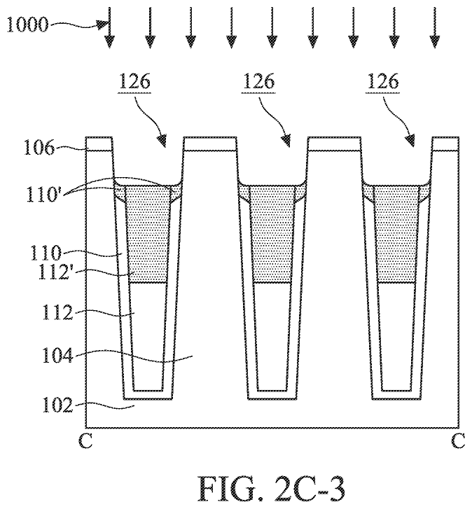

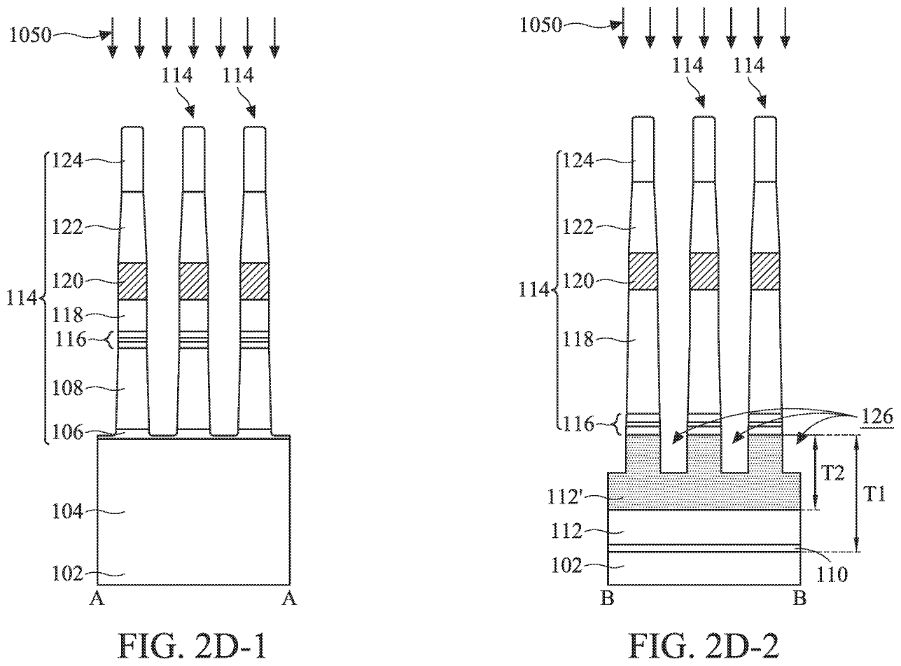

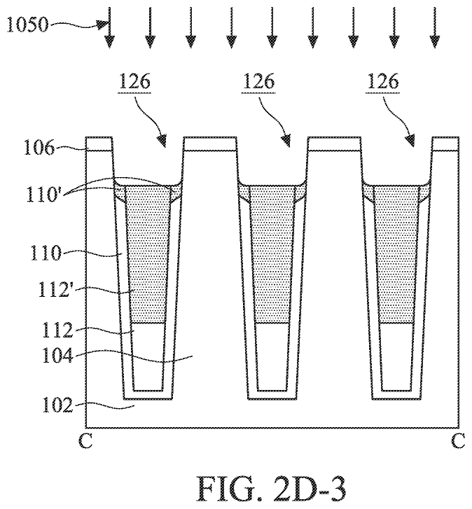

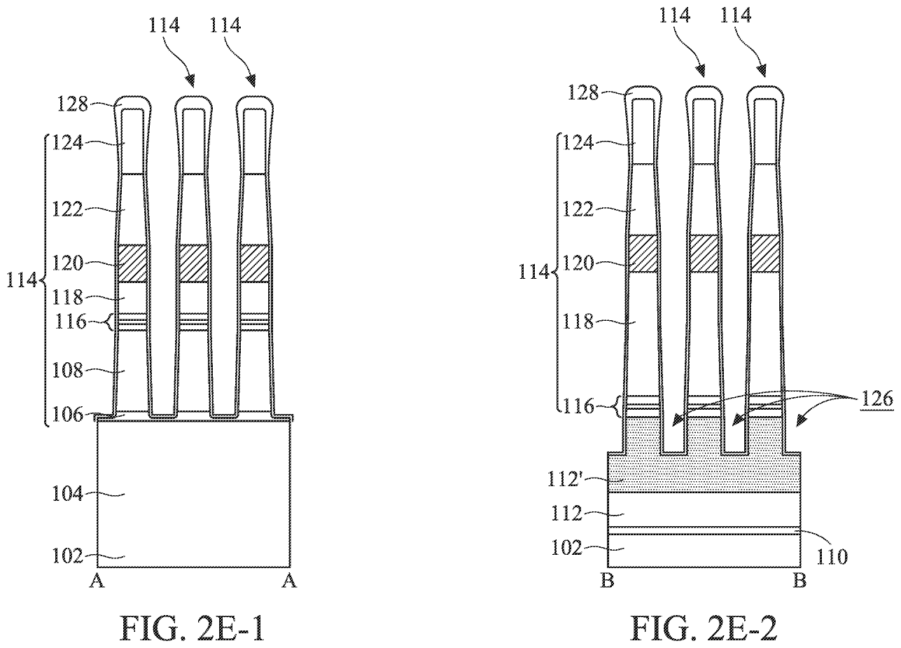

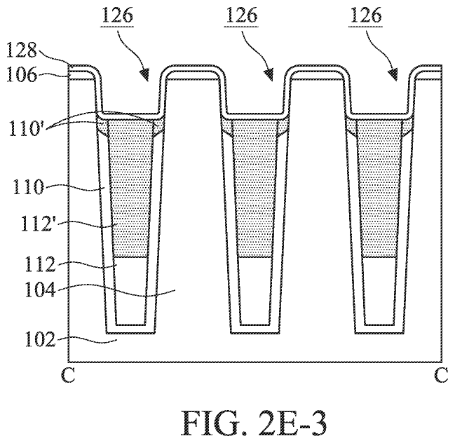

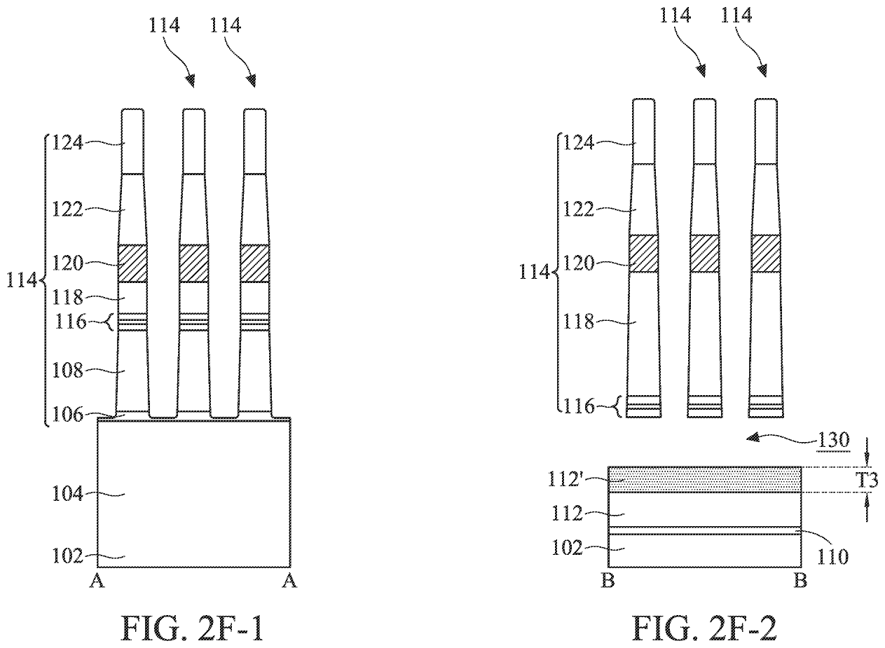

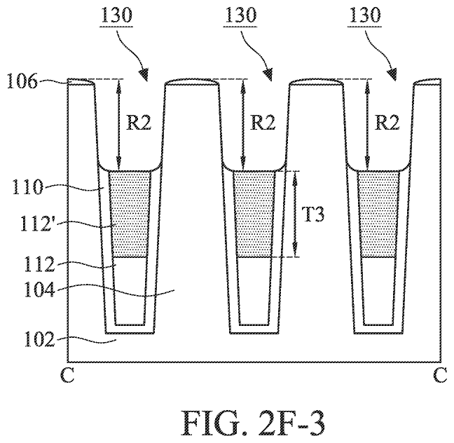

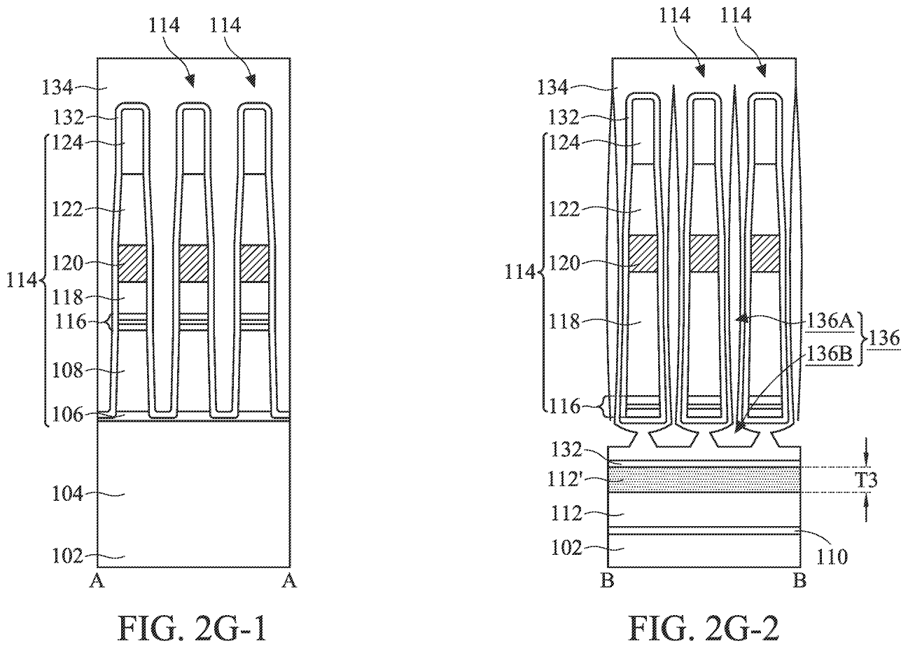

FIGS. 2A-1 through to 2G-3 illustrate cross-sectional views of forming the flash memory 100 of FIG. 1 at various stages, in accordance with some embodiments of the present disclosure. FIGS. 2A-1 to 2G-1, FIGS. 2A-2 to 2G-2, and FIGS. 2A-3 to 2G-3 correspond to cross-section A-A, cross-section B-B, and cross-section C-C of FIG. 1, respectively.

FIGS. 2A-1, 2A-2 and 2A-3 illustrate the flash memory after the formation of active regions 104 and an isolation layer 112. In some embodiments, a substrate 102 is provided. The substrate 102 may be an elemental semiconductor substrate, such as a silicon or germanium substrate, or a compound semiconductor substrate, such as a silicon carbide or gallium arsenide substrate. In some embodiments, the substrate 102 may be a semiconductor-on-insulator (SOI) substrate.

A tunneling oxide 106 and a first semiconductor layer 108 are sequentially formed over the substrate 102. The tunneling oxide 106 may be made of silicon oxide. The first semiconductor layer 108 may include doped polysilicon material. A pattered mask layer (not shown) may be formed over the first semiconductor layer 108, and the first semiconductor layer 108, the tunneling oxide 106 and the underlying substrate 102 are etched using the pattered mask layer to form trenches. The portion of the substrate 102 protruding from between the trenches forms active regions 104.

A lining layer 110 is formed along the first semiconductor layer 108, the tunneling oxide 106, the active regions 104 and the substrate 102 to partially fill the trenches. The lining layer 110 may be made of a dielectric material such as silicon oxide, silicon nitride, silicon oxynitride, or a combination thereof. An isolation layer 112 are formed over the lining layer 110 to overfill the trenches. The isolation layer 112 may be made of silicon oxide-based material such as spin-on-glass (SOG), which is deposited using a spin-on coating process followed by an anneal or curing process. In some embodiment, the isolation layer 112 is non-doped, for example, having a concentration of the dopant (e.g., phosphorous) less than 10¹⁴ cm⁻³.

A planarization process such as chemical mechanical polishing (CMP) or etch-back process is performed on the isolation layer 112 and the lining layer 110 until the patterned mask layer (not shown) is exposed. An etching back process is then performed to expose the sidewalls of the first semiconductor layers 108. In some embodiments, the isolation layer 112 along with the underlying lining layer 110 has thickness T1 in a range from about 150 nm to about 200 nm.

FIGS. 2B-1, 2B-2 and 2B-3 illustrate the flash memory after the formation of gate stacks 114. Gate stacks 114 are formed over the active regions 104 and the isolation layer 112. Each of the gate stacks 114 includes the tunneling oxide 106, the first semiconductor layer 108, an inter-gate dielectric layer 116, a second semiconductor layer 118, a conductive layer 120, a first mask layer 122 and a second mask layer 124. The first semiconductor layer 108 can be configured as the floating gate of the resulting flash memory devices, while the second semiconductor layer 118 can be configured as the control gate of the resulting flash memory devices. The conductive layer 120 can be configured as the word line of the resulting flash memory devices.

The formation of gate stacks 114 includes sequentially depositing the inter-gate dielectric layer 116, the second semiconductor layer 118, the conductive layer 120, the first mask layer 122 and the second mask layer 124. The second semiconductor layer 118 may include doped polysilicon material. The inter-gate dielectric layer 116 may be a tri-layer structure including oxide-nitride-oxide (ONO). The conductive layer 120 may include tungsten (W), titanium (Ti), tantalum (Ta), tungsten nitride (WN), titanium nitride (TiN), tantalum nitride (TaN), cobalt silicide (CoSi), nickel silicide (NiSi), or tungsten silicide (WSi). The first and second mask layer 122 and 124 may be made of dielectric material, such as silicon nitride (SiN), silicon oxynitride (SiON), silicon oxide (SiO), other suitable materials, and/or combinations thereof.

A patterning process is performed on the mask layers 124 and 122, the conductive layer 120, the second semiconductor layer 118, the inter-gate dielectric layer 116, the first semiconductor layer 108, and the tunneling oxide 106 using photolithography and etching process, thereby forming the gate stacks 114. After the etching process. the tunneling oxide 106 uncovered by the gate stacks 114 remains on the top surfaces of the active regions 104.

In the etching process for forming the gate stacks 114, portions of the lining layer 110 and the isolation layer 112 uncovered by the gate stacks 114 may be recessed to form recess 126. In some embodiments, the recess 126 have a depth R1 in a range from about 30 nm to about 80 nm. In some embodiments, the ratio of the depth R1 to the thickness T1 is in a range from about 0.15 to about 0.53. If the ratio is too small, the dimension (or volume) of subsequently formed air gaps may be too small. If the ratio is too large, the variation of the depths R1 of the recesses 126 between different locations may be too large, leading to worse uniformity of the dimensions of the subsequently formed air gaps. This may cause a large difference in electrical characters of the resulting flash memory devices between different locations.

FIGS. 2C-1, 2C-2 and 2C-3 illustrate the flash memory after an implantation process 1000. An implantation process 1000 is performed on the flash memory 100 to introduce dopants into the isolation layer 112. The upper portion of the isolation layer 112 are doped to form a doped isolation layer 112′. The doped isolation layer 112′ may have a faster etching rate than the non-doped isolation layer 112 in a following etching process, which may improve the variation (i.e., decrease) of the etching rate of the doped isolation layer 112′ between different locations in the following etching process.

The implantation process 1000 may be performed using a high-current ion implanter, or the like. In the implantation process 1000, implantation species (or dopants) are introduced using various ion species that are ionized and accelerated to inject into the flash memory 100 using a number of ion beams. In some embodiments, the implantation species (or dopants) may include phosphorous (P), boron (B), another suitable implantation species, a combination thereof, or the like.

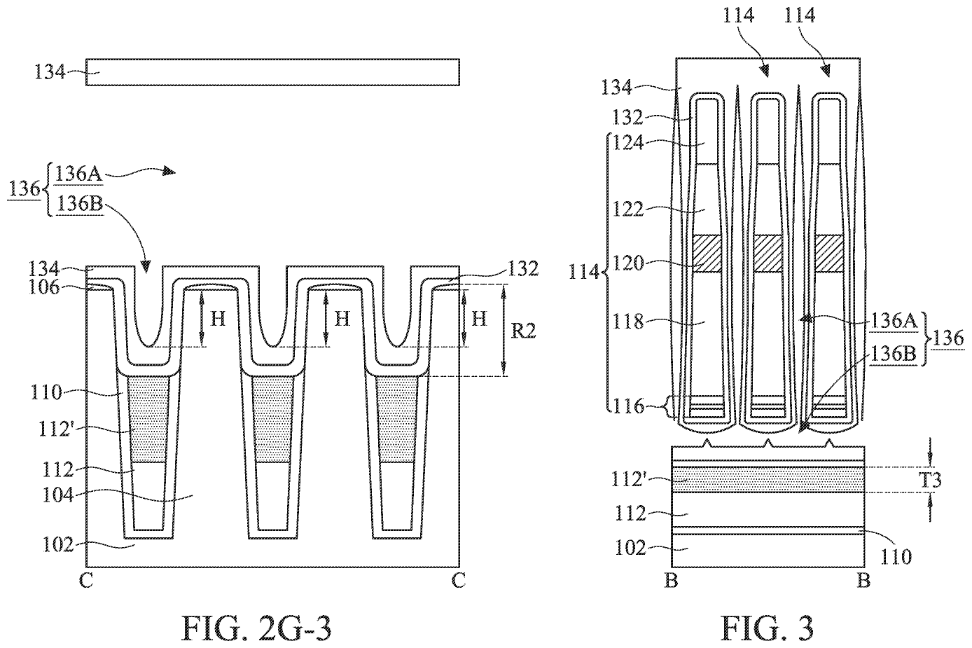

The tunneling oxide 106 may protect the active regions 104, and thus the active regions 104 is substantially undoped or slightly doped with the dopants in the implantation process 1000. As a result, the tunneling oxide 106 uncover by the gate stacks 114 are also doped with the dopants. In addition, the upper portion of the lining layer 110 are doped to form a doped lining layer 110′. As shown in FIG. 2C-3, the doped isolation layer 112′ extends to a deeper position than the doped lining layer 110′.

FIGS. 2D-1, 2D-2 and 2D-3 illustrate the flash memory after an anneal process 1050. An anneal process 1050 is performed on the flash memory 100 to drive the dopants into a deeper position, thereby enlarging the thickness of the doped isolation layer 112′. After the anneal process 1050, the doped isolation layer 112′ has a thickness T2 in a range from about 50 nm to about 100 nm. In some embodiments, the ratio of the thickness T2 to the thickness T1 is in a range from about 0.25 to about 0.67. If the ratio is too small, the variation of the etching rate of the doped isolation layer 112′ between different locations may be not sufficient improved. If the ratio is too large, the gate stacks 114 may be negatively affected because the annealing process 1050 requires higher temperatures and/or longer time periods to drive the dopants to deeper position.

In some embodiments, the anneal process 1050 may be a rapid thermal anneal (RTA) process. The anneal process 1050 is performed at a temperature of about 900° C. to about 1000° C. for a time period less than 1 second, and in an ambient of N₂, Ar, or a combination thereof.

FIGS. 2E-1, 2E-2 and 2E-3 illustrate the flash memory after the formation of a protection layer 128. A protection layer 128 is form over the flash memory 100 to partially fills the recesses 126 and the space between the gate stacks 114. The protection layer 128 may be made of a dielectric material such as silicon oxide, silicon nitride, silicon oxynitride, or a combination thereof. The protection layer 128 is configured to prevent the active regions 104 from being damaged in the subsequent etching process.

FIGS. 2F-1, 2F-2 and 2F-3 illustrate the flash memory after an etching process. An etching process is performed on the flash memory 100 to recess the doped isolation layer 112′, the doped lining layer 110′ and the lining layer 110. In some embodiments, the etching process may be isotropic etching such as wet etching, for example, using dilute hydrofluoric acid. In etching process, the protection layer 128 is removed. The recesses 126 are enlarged vertically to a depth R2 that is measured downward from the upper surface of the tunneling oxide 106, and enlarged laterally and connected to each other to form trenches 130.

Because the doped isolation layer 112′ have a faster etching rate in the etching process, the variation of the depths R2 of the trenches 130 between different locations may be better compared with the case where the trenches 130 are formed by directly recessing the non-doped isolation layer 112. The remaining doped isolation layer 112′ has a thickness T3 less than about 10 nm. In some embodiments, the doped isolation layer 112′ may be completely removed (i.e., thickness T3 is zero) in the etching process to expose the isolation layer 112.

FIGS. 2G-1, 2G-2 and 2G-3 illustrate the flash memory after the formation of a lining layer 132, an isolation layer 134 and air gaps 136. A lining layer 132 is conformally formed along the flash memory 100 to partially fill the trenches 130. The lining layer 132 may be made of a dielectric material such as silicon oxide, silicon nitride, silicon oxynitride, or a combination thereof. An isolation layer 134 is formed over the lining layer 132 to fill the trenches 130 and the space between the gate stacks 114. The isolation layer 134 may be made of a dielectric material such as silicon oxide, silicon nitride, silicon oxynitride, or a combination thereof. In some embodiment, the isolation layer 134 is non-doped, for example, having a concentration of the dopant (e.g., phosphorous) less than 10¹⁴ cm⁻³.

The isolation layer 134, the doped isolation layer 112′ and the isolation layer 112 may collectively serve as the isolation structure IS as shown in FIG. 1. The isolation layer 112 surrounds the lower portions of the active regions 104, the doped isolation layer 112′ surrounds the middle portions of the active regions 104, and the isolation layer 134 surrounds the upper portions of the active regions 104.

The trenches 130 and the space between the gate stacks 114 are sealed by the isolation layer 134, thereby forming into multiple air gaps 136. The air gaps 136 include first portions 136A which extends in the first direction D1 between neighboring gate stacks 114 and second portions 136B which are formed between neighboring active regions 104 and neighboring gate stacks 114. As shown in FIG. 2G-2, in the second direction D2, the second portions 136B in a row are isolated from each other by the isolation layer 134. As shown in FIG. 2G-3, each of the first portions 136A is connected to a column of second portions 136B in the first direction D1. In some embodiments, the second portions 136B may extend to locations directly below the gate stacks 114. The tops of the first portions 136A may be higher than the top surfaces of the gate stacks 114.

Because the depths R2 of the trenches 130 have a lower variation between different locations, the depths H of the air gaps 136 at different locations, which are measure downward from the upper surface of the active region 104, may also have a lower variation, as shown in FIG. 2G-3. Therefore, the difference in electric characters (e.g., data retention, and/or cross-talk between cells during operations such as program, erase, etc.) of the resulting flash memory devices between different locations may be improved.

FIG. 3 is a modification of the flash memory of FIG. 2G-2, in accordance with some embodiments of the present disclosure. The embodiments of FIG. 3 are similar to the embodiments of FIG. 2A-1 through 2G-3, except that the second portions 136B of the air gaps 136 in a row are connected to each other, thereby continuously extending below in the gate stacks 114 in the second direction D2.

As described above, by doping the isolation layer 112 to increase the etching rate, the variation of the etching rate of the doped isolation layer 112′ between different locations may be improved. Therefore, the air gaps 136 are formed to have the dimension with a lower variation, and thus the difference in electric characters of the resulting flash memory devices between different locations may be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory, comprising:
a plurality of active regions over a substrate;
a first isolation layer surrounding lower portions of the active regions;
a plurality of gate stacks across the active regions; and
a second isolation layer surrounding upper portions of the active regions, wherein an air gap is located in the second isolation layer and includes a first portion between a first gate stack and a second gate stack in the plurality of gate stacks and a second portion between a first active region and a second active region in the plurality of active regions.

2. The flash memory as claimed in claim 1, further comprising:
a third isolation layer surrounding middle portions of the active regions between the upper portions of the active regions and the lower portions of the active regions, wherein a dopant concentration of the third isolation layer is higher than a dopant concentration of the first isolation layer.

3. The flash memory as claimed in claim 2, wherein the second isolation layer is doped with phosphorous, boron, or a combination thereof.

4. The flash memory as claimed in claim 1, wherein the second portion of the air gap extends directly below the first gate stack and the second gate stack.

5. The flash memory as claimed in claim 1, wherein a top of the first portion of the air gap is located higher than top surfaces of the gate stacks.

6. The flash memory as claimed in claim 1, wherein the second portion of the air gap continuously extends below the plurality of gate stacks.

7. The flash memory as claimed in claim 1, wherein the second isolation layer includes a portion that extends below the plurality of gate stacks.

8. The flash memory as claimed in claim 1, wherein the air gap includes a third portion between a third active region and the second active region, wherein the first portion of the air gap is connected to the second portion and third portion of the air gap.

9. The flash memory as claimed in claim 1, further comprising:
a lining layer between the second isolation layer and the upper portions of the active regions.

10. The flash memory as claimed in claim 1, wherein each of the gate stacks includes a floating gate and a control gate over the floating gate.

11. A method for forming a flash memory, comprising:
forming an isolation layer to surround a plurality of active regions;
forming a plurality of gate stacks across the active regions and the isolation layer;
implanting a dopant into an upper portion of the isolation layer to form a doped isolation layer;
partially recessing the doped isolation layer; and
forming a dielectric material over the plurality of gate stacks, the plurality of active regions and the doped isolation layer.

12. The method for forming the flash memory as claimed in claim 11, further comprising:
performing an anneal process on the doped isolation layer after implanting the dopant into the upper portion of the isolation layer and before partially recessing the doped isolation layer.

13. The method for forming the flash memory as claimed in claim 12, wherein the anneal process is performed at a temperature of about 900° C. to about 1000° C.

14. The method for forming the flash memory as claimed in claim 11, further comprising:
forming a lining layer along sidewalls of the plurality of active regions, wherein the isolation layer is formed over the lining layer; and
implanting the dopant into an upper portion of the lining layer to form a doped lining layer while implanting the dopant into the upper portion of the isolation layer.

15. The method for forming the flash memory as claimed in claim 14, further comprising:
completely removing the doped lining layer while partially recessing the doped isolation layer.

16. The method for forming the flash memory as claimed in claim 11, further comprising:
forming a protection layer along the plurality of gate stacks and the doped isolation layer before partially recessing the doped isolation layer.

17. The method for forming the flash memory as claimed in claim 11, wherein forming the plurality of gate stacks across the active regions and the isolation layer comprises:
sequentially depositing an inter-gate dielectric layer, a semiconductor layer, and a conductive layer; and
etching the inter-gate dielectric layer, the semiconductor layer, the conductive layer and recessing the isolation layer.

18. The method for forming the flash memory as claimed in claim 11, wherein the isolation layer has a plurality of recesses between the plurality of gate stacks, and partially recessing the doped isolation layer comprises enlarging the plurality of recesses so that the recesses are connected to each other to form a trench.

19. The method for forming the flash memory as claimed in claim 18, wherein the dielectric material seals the trench to form a plurality of air gaps.

20. The method for forming the flash memory as claimed in claim 11, wherein the dopant includes phosphorous, boron, or a combination thereof.
